(19) United States
(12) Patent Application Publication
(10) Pub. No.: US 2015/0171235 A1
(43) Pub. Date: Jun. 18, 2015

(54) AVOIDANCE OF GLASS BENDING IN THERMAL PROCESSES

(71) Applicant: Saint-Gobain Glass France, Courbevoie (FR)

(72) Inventors: Stefan Jost, Munchen (DE); Jörg Palm, Munchen (DE)

(21) Appl. No.: 14/415,811

(22) PCT Filed: Jul. 18, 2013
(86) PCT No.: PCT/EP2013/065254

§ 371 Date: Jan. 20, 2015

(30) Foreign Application Priority Data
Jul. 19, 2012 (EP) 12177106.7

(51) Int. Cl. H01L 31/0216; H01L 31/18

(52) U.S. Cl. CPC H01L 31/02167; H01L 31/18

(57) ABSTRACT

The present invention relates to a multilayer body arrangement 1 for the prevention of glass substrate deformation, comprising at least:
a glass substrate 30,
a functional coating 10, which is applied on one side of the glass substrate 30,
an auxiliary layer 20, which is connected over its entire area to the side of the glass substrate 30 facing away from the functional coating 10,
at least one emitter array 4 with a radiated power Pₜₒₜ in the wavelength range from 250 nm to 4000 nm incident on the glass substrate 30 for heat-treating the functional coating 10,
wherein the auxiliary layer 20 has an absorbed radiated power P₂₀ from 10% to 60% of the incident radiated power Pₜₒₜ.

The invention relates to a multilayer body arrangement and a method for heat-treating a multilayer body, in particular for producing a thin-film solar cell, with little deformation of the glass substrate.

Photovoltaic layer systems for the direct conversion of sunlight into electrical energy are sufficiently well known. The materials and the arrangement of the layers are coordinated such that incident radiation is converted directly into electrical current by one or a plurality of semiconducting layers with the highest possible radiation yield. Photovoltaic and extensive-area layer systems are referred to as solar cells.

Solar cells contain, in all cases, semiconductor material. Solar cells that require carrier substrates to provide adequate mechanical strength are referred to as thin-film solar cells. Due to the physical properties and the technological handling qualities, thin-film systems with amorphous, micromorphous, or polycrystalline silicon, cadmium telluride (CdTe), gallium arsenide (GaAs), or copper indium (gallium) sulfur/selenium (Cu(In,Ga)(S,Se)₂) are particularly suited for solar cells. The pentenary semiconductor Cu(In,Ga)(S,Se)₂ belongs to the group of chalcopyrite semiconductors that are frequently referred to as CIS (copper indium diselenide or sulfide) or GIGS (copper indium gallium diselenide, copper indium gallium disulfide, or copper indium gallium disulfoselenide). In the abbreviation GIGS, S can represent selenium, sulfur, or a mixture of the two chalcogens.

In many cases, carrier substrates for thin-film solar cells include inorganic glass. Due to the widely available carrier substrate and a simple monolithic serial connection, large-area arrangements of thin-film solar cells can be produced cost-effectively.

A possible method for producing thin-film semiconductors, for example, made of Cu(In,Ga)(S,Se)₂ consists of a two-stage process. Such two-stage methods are known, for example, from J. Palm et al., “CIS module pilot processing applying concurrent rapid selenization and sulfurization of large area thin film precursors”, Thin Solid Films 431-432, pp. 414-522 (2003). There, first, an electrode made of molybdenum is applied on a substrate, for example, a glass substrate. The molybdenum layer is patterned, for example, with a laser. Then, various precursor layers made of copper, indium, and gallium are deposited on the molybdenum layer, for example, by magnetron cathode sputtering. Also, a selenium layer and/or a sulfur layer are/is deposited on the layer sequence by thermal evaporation. The multilayer body with the precursor layers thus developed is heat-treated in a second process. The actual crystal formation and phase conversion of the precursor layers to form the actual semiconductor layer takes place by means of the heat treatment.

The heat treatment occurs, for example, in in-line systems, in which the various process steps occur in different chambers. The different chambers are traversed one after another in a process line. In a simplified structure, an in-line system consists of a loading station, in which the system is loaded with untreated multilayer bodies. Then, the multilayer bodies are transported via an intake air lock chamber into the in-line system. In different heating chambers, the multilayer bodies are heated very rapidly with heating rates up to 50° C./s and exposed to a specified temperature cycle. The heating is performed, for example, by electrically operated radiant heaters. The method for rapid thermal processing of individual precursor layers into a semiconductor compound is commonly referred to as rapid thermal processing (RTP). Next, the multilayer body is cooled in cooling chambers and/or a cooling line and discharged from the system through an air lock. A method for rapid thermal processing of chalcopyrite semiconductors for use as absorbers in thin-film solar cells is known, for example, from EP 0 662 247 B1.

For better control of the heat-treating process, the process space around the multilayer body can be restricted, for example, by a temporary process box, as is known from DE 10 2008 022 784 A1. By restricting the process space, the partial pressure of the readily volatile chalcogen components such as selenium or sulfur remains largely constant during the heat treatment. In addition, the exposure of the process chamber to corrosive gases is reduced. Methods for processing two glass substrates in one process box, so-called “dual substrate methods” are known, for example, from EP 2 360 720 A1 and EP 2 360 721 A1.

Due to the high temperatures, uncontrolled deformation of the glass substrates used as carrier substrates frequently occurs during the RTP process. The deformation of the glass substrates is disadvantageous for the further process steps such that further processing is difficult or impossible.

The object of the present invention consists in providing an improved multilayer body arrangement that has reduced deformation of the glass substrate during heat treatment.

The object of the present invention is accomplished according to the invention by a multilayer body arrangement according to claim 1. Preferred embodiments emerge from the subclaims.

The invention further includes a method for heat-treating multilayer bodies with reduced substrate deformation.

A use of the multilayer body arrangement according to the invention emerges from other claims.

In the context of the invention, the term “multilayer body” describes at least one substrate and in particular a glass substrate with a plurality of same or different layers applied or disposed thereon in direct, thermal contact thereon.

The inventors identified the following surprising, causal chain of problems that lead to substrate deformation during the heat treatment of a glass substrate with a coating on one side. When a glass substrate with a coating on one side, for example, a functional coating consisting of a barrier layer, an electrode, and precursor layers, is heated in an emitter array, this leads to an inhomogeneous temperature distribution over the substrate thickness z. As a rule, the functional coating absorbs more radiation than the glass substrate. As a result, the side with the functional coating is heated more than the side of the glass substrate facing away from the coating. The inhomogeneous temperature distribution leads to a different expansion of the coated side and the uncoated side. This results in stresses in the arrangement made of a glass substrate and a functional coating and in deformation of the glass substrate in the hot state. When the glass substrate is heated above the glass softening temperature of, for example, roughly 470° C. for soda lime glass, a mechanical relaxation of stresses occurs due to the viscoelasticity of the glass. The side with less heating and, consequently, less thermal expansion can expand due to the softening of the glass and under the glass substrate's own weight. The glass substrate then again rests flat on, for example, a base plate. The glass substrate has a temperature gradient between the coated and uncoated side. When the glass substrates cools after the radiated power is turned off, this results in deformation in the opposite direction due to the greater thermal contraction of the hotter side of the glass substrate. When the glass substrate is cooled below the glass softening temperature, relaxation no longer occurs in the glass substrate. The glass substrate presents marked deformation after cooling.

Such substrate deformation is unexpectedly prevented or reduced by a multilayer body arrangement according to the invention.

The multilayer body arrangement for the prevention of glass substrate deformation according to the invention comprises at least
a glass substrate,
a functional coating, which is applied on one side of the glass substrate,
an auxiliary layer, which is connected over its entire area to the side of the glass substrate facing away from the functional coating, and
at least one emitter array with a radiated power Rₜₒₜ in the wavelength range from 250 nm to 4000 nm incident on the glass substrate for heat-treating the functional coating.

The auxiliary layer has an absorbed radiated power P₂₀ from 10% to 60% of the incident radiated power Pₜₒₜ.

In an advantageous embodiment of the multilayer body arrangement according to the invention, the auxiliary layer is applied directly on the glass substrate, preferably by vapor deposition, cathode sputtering, or electrochemical deposition.

In an advantageous embodiment of the multilayer body arrangement according to the invention, the auxiliary layer is releasably connected to the glass substrate. The auxiliary layer is then applied preferably on a carrier plate. The glass substrate can be clamped or laid on the auxiliary layer on the carrier plate. Alternatively, the carrier plate can be laid on or clamped on the glass substrate with the side coated by the auxiliary layer. The auxiliary layer is preferably applied on a base plate or a cover plate of a process box.

The glass substrate, the functional coating, and the auxiliary layer can, without restricting the invention, have a plurality of layers disposed one over another or next to another.

The radiated power Pₜₒₜ in the wavelength range from 250 nm to 4000 nm incident from the at least one emitter array is preferably from 10 kW/m² to 500 kW/m² and particularly preferably from 50 kW/m² to 200 kW/m².

In an advantageous embodiment of the invention, the radiated power Pₜₒₜ in the wavelength range from 400 nm to 2500 nm incident from the at least one emitter array is from 10 kW/m² to 500 kW/m² and preferably from 50 kW/m² to 200 kW/m².

The auxiliary layer according to the invention preferably absorbs an absorbed radiated power P₂₀ of 10% to 40% and particularly preferably of 20% to 30% of Pₜₒₜ.

In an advantageous embodiment, the auxiliary layer absorbs a radiated power P₂₀ of 50% to 150% and preferably of 75% to 125% of the radiated power P₁₀ absorbed in the functional coating.

The device according to the invention for heat-treating the multilayer body comprises at least one emitter array. In an advantageous embodiment, the device comprises two emitter arrays with a process level lying therebetween, in which the multilayer body is disposed. The emitter arrays and the process level are disposed preferably parallel to each other.

In advantageous embodiments of the device according to the invention, the emitter arrays, the process level, and the multilayer body are disposed vertically or horizontally. A vertical arrangement in the context of the invention means that the emitter arrays, the process level, and the multilayer body are disposed approx. parallel to the base of the system. In a horizontal arrangement, the emitter arrays, process level, and multilayer body are disposed approx. perpendicular to the base of the system.

The auxiliary layer according to the invention is advantageously inert relative to the process products of the functional coating during heat treatment and, in particular, inert relative to sulfur vapors and selenium vapors as well as to hydrogen sulfide and hydrogen selenide. The auxiliary layer preferably includes at least one layer made of graphite, silicon carbide, and/or boron nitride, preferably with a layer thickness of 10 nm to 10 μm. This has the particular advantage that the auxiliary layer is temperature-stable and chemically inert relative to the process products during the heat treatment.

In an alternative embodiment of the auxiliary layer according to the invention, the auxiliary layer includes an absorption layer and a protective layer. The absorption layer is disposed between a glass substrate and the protective layer. According to the invention, the absorption layer absorbs the electromagnetic radiation of the emitter array and can include materials that can be corroded by the process products such as sulfur or selenium. Suitable materials for the absorption layer are, for example, metal, preferably aluminum, molybdenum, copper, cobalt, nickel, titanium, and/or tantalum. Alternatively, the absorption layer can include semiconductors or metalloid compounds, preferably silicon carbide, zinc oxide, cadmium sulfide, cadmium telluride, indium antimonide, indium arsenide, and/or zinc antimonide.

The protective layer protects the absorption layer against corrosive process products and preferably includes silicon nitride, titanium nitride, molybdenum nitride, aluminum oxide, and/or aluminum nitride.

In an advantageous improvement of the auxiliary layer according to the invention, an adhesive layer is disposed between the glass substrate and the absorption layer. The adhesive layer increases the adhesion of the absorption layer to the glass substrate and includes, for example, silicon nitride and/or silicon oxynitride.

The adhesive layer, absorption layer, and/or protective layer preferably form a diffusion barrier against alkali metals out of the glass substrate.

In another preferred embodiment, the multilayer body to be processed includes a glass substrate with a thickness of 1 mm to 4 mm, preferably of 2 mm to 3 mm. The glass is preferably low-iron soda lime glass. Such glass has a glass softening temperature of roughly 470° C.

The functional coating preferably contains precursor layers for conversion into a semiconductor absorber layer of a thin-film solar cell. The multilayer body arrangement according to the invention is, in principle, suitable for heat-treating all precursor layers that are to be converted into semiconductor absorber layers of thin-film solar cells and reduces deformation of the glass substrate there.

For producing a Cu(In,Ga)(S,Se)₂-thin-film solar cell, the functional coating preferably includes at least one alkali diffusion barrier made of silicon nitride, one electrode layer made of molybdenum, one precursor layer made of copper-indium-gallium, and an additional precursor layer made of selenium. The silicon nitride layer has a thickness of, for example, 50 nm to 300 nm, the molybdenum layer of, for example, 200 nm to 700 nm, the copper-indium-gallium layer of, for example, 300 nm to 1000 nm, and the selenium layer of, for example, 700 nm to 2000 nm.

In a preferred embodiment of the device according to the invention, at least one multilayer body, preferably two multilayer bodies are situated in a process box. The process box serves to delimit the process space.

The process box can be designed as a box with a floor, cover, and sidewalls. The sidewalls can include metal, glass, ceramic, glass ceramic, or graphite. The floor and cover are preferably transparent or partially transparent, in particular to the electromagnetic radiation of the emitter arrays.

The process boxes can be designed quasi gas tight or open. The process boxes can preferably have their own gas connections and be provided with a specific gas atmosphere during specific process steps. The gas atmosphere can, for example, include reactive gases such as H₂S, H₂Se, S-vapor, Se-vapor, or H₂ as well as inert gases such as N₂, He, or Ar.

In the context of the invention, “quasi gas tight” means that the process box is gas tight up to a defined maximum pressure difference between the interior of the process box and the process chamber. When a defined maximum pressure difference is exceeded, a pressure equalization between the interior of the process box and the process chamber occurs. In a suitable design for this, the cover is placed loosely on the frame of the process box. Depending on the tightness of the process box, with quasi gas tight process boxes, a pressure difference between the interior of the process box and the process chamber can be maintained. The free exchange of process gas remains limited and a partial pressure drop of the process gas develops.

In a preferred embodiment of the device according to the invention, a process box is loaded with, in each case, two multilayer bodies. For the processing of two multilayer bodies in one process box, the two glass substrates can be disposed next to each other such that the two functional coatings face outward. Alternatively, the two functional coatings can face each other. In the “facing each other” case, the two functional coatings are preferably separated from each other by spacing means such that a process gas can be fed into the space created.

In the advantageous embodiment of the arrangement according to the invention, the multilayer bodies or the process boxes loaded with multilayer bodies are moved through the device by a transport mechanism. The transport mechanism can, for example, include a conveyor belt, conveyor chains, or a sled. The transport mechanism can preferably include rollers that are, particularly preferably, synchronously driven by V-belts or chain drives, preferably with a drive unit located outside the process chamber.

In a preferred embodiment of the device according to the invention, the emitter arrays include linear emitters known per se, in particular electrically operated rod-shaped infrared emitters and/or a matrix of point beam sources known per se. The linear emitters are preferably placed in parallel next to each other. Linear emitters and point beam sources are suitable to emit virtually uniform area-wise electromagnetic radiation in the wavelength range from 250 nm to 4000 nm and preferably in the thermal radiation range.

In one embodiment of the device according to the invention, each emitter array emits electromagnetic radiation of equal intensity toward both sides. In a preferred embodiment of the device according to the invention, the emitter arrays have direction-dependent emission characteristics, in particular in the direction of the process level. For this, linear emitters are, for example, used that have a reflective coating on one side, made, for example, of ceramic, metal, or nanoporous opaque quartz glass, as is known from DE 10 2005 058819 A1.

In another preferred embodiment of the device according to the invention, the emitter array that is situated between two process levels comprises two levels of linear emitters or point beam sources, disposed one beneath another. Another reflector is preferably disposed between the two levels. The two levels can be heated separately from each other. Different process levels can thus be heated to different temperatures.

By means of emitter arrays with different power or emitter arrays with a direction-dependent emission characteristic, different sides of a multilayer body can, in particular, be heated with different heat inputs. The symmetrization according to the invention of the temperature distribution in the direction of the layer thickness through the glass substrate can be supported by this measure.

The object of the invention is further accomplished by a method for heat-treating a glass substrate with a functional coating, wherein, in a first step, the functional coating is applied on one side of the glass substrate. Moreover, the side of the glass substrate facing away from the functional coating is connected to an auxiliary layer.

The auxiliary layer can be applied directly on the glass substrate, for example, by vapor deposition, cathode ray sputtering, chemical gas phase deposition, electrodeposition, or spray methods.

Alternatively, the auxiliary layer can be disposed on a carrier material such as a carrier plate, and the glass substrate can be connected to the auxiliary layer of the carrier material, e.g., by clamping or placement thereon.

In a second step, the glass substrate with the functional coating and the auxiliary layer is heated in an emitter array to a temperature above the glass softening temperature of the glass substrate. The process temperature is preferably from 470° C. to 600° C.

In a third step, the glass substrate is cooled to a temperature below the glass softening temperature. The glass softening temperature of low-iron soda lime glass is roughly 470° C.

A preferred use of the multilayer body arrangement according to the invention is the conversion of precursor layers into a semiconductor layer, preferably at temperatures from 470° C. to 600° C. The semiconductor layer is preferably used as an absorber in a thin-film solar cell.

The precursor layers preferably contain or are made of copper, indium, gallium, and selenium and are converted into a Cu(In,Ga)(S,Se)₂-semiconductor layer in a sulfur-containing atmosphere by rapid thermal processing (RTP).

In the following, the invention is explained in detail with reference to figures. The figures are purely schematic representations and are not true to scale. The figures in no way restrict the invention.

They depict:

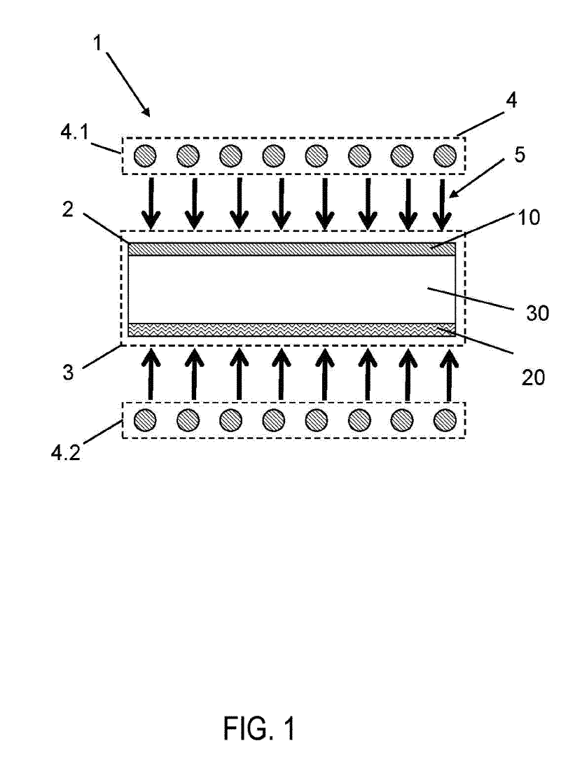

FIG. 1 a schematic cross-sectional representation of a multilayer body arrangement according to the invention,

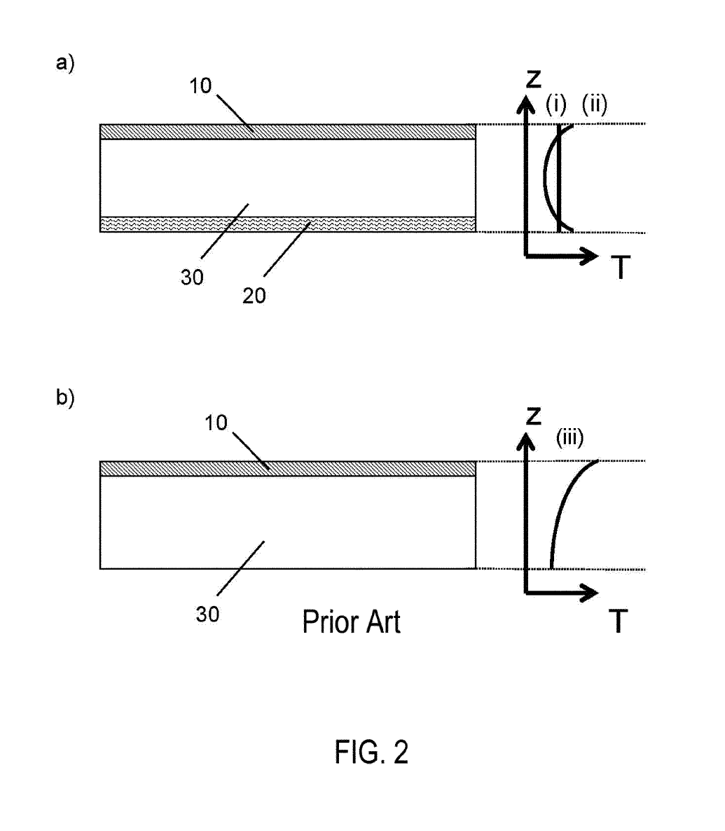

FIG. 2a a cross-section through a multilayer body according to the invention with a temperature profile,

FIG. 2b a cross-section of a multilayer body according to the prior art with a temperature profile,

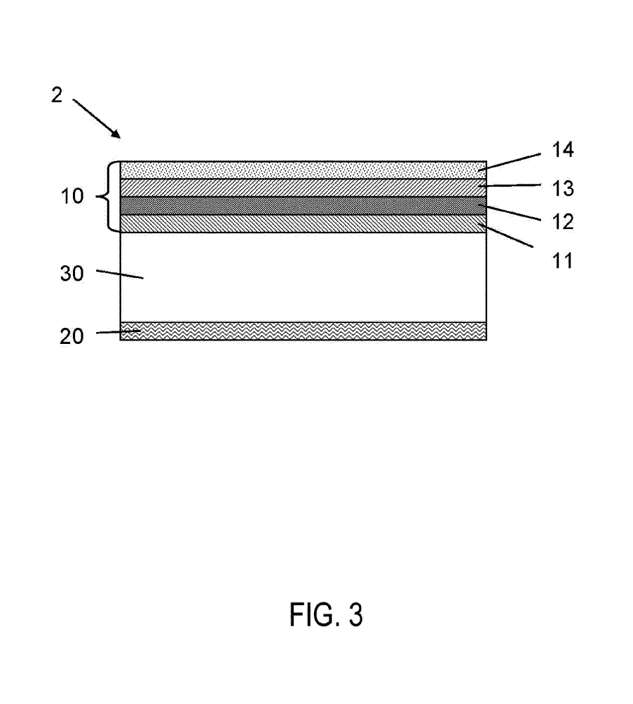

FIG. 3 a cross-section through an embodiment of the multilayer body according to the invention,

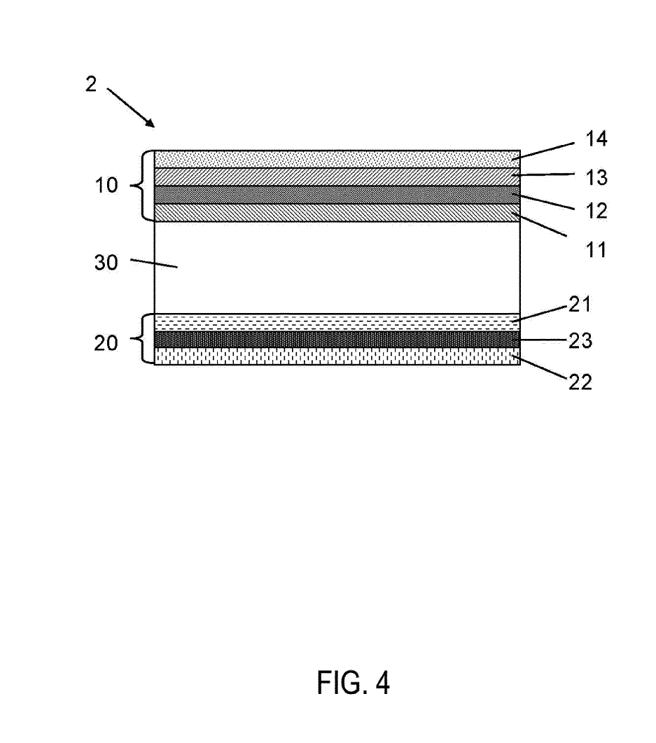

FIG. 4 a cross-section through another embodiment of the multilayer body according to the invention,

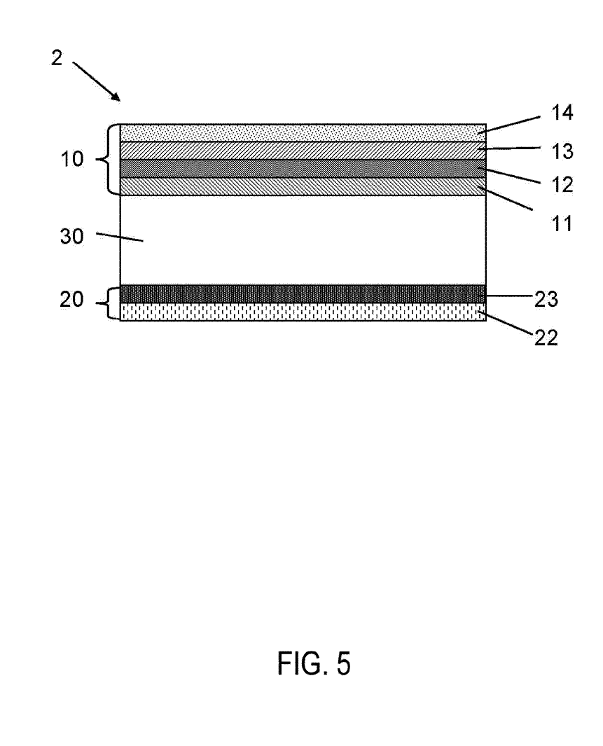

FIG. 5 a cross-section through another embodiment of the multilayer body according to the invention,

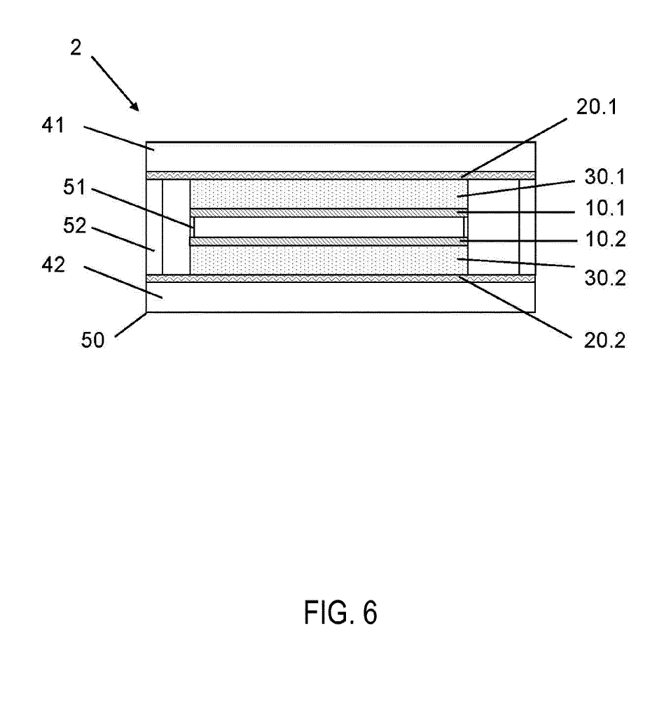

FIG. 6 a cross-section through another embodiment of the multilayer body according to the invention, and

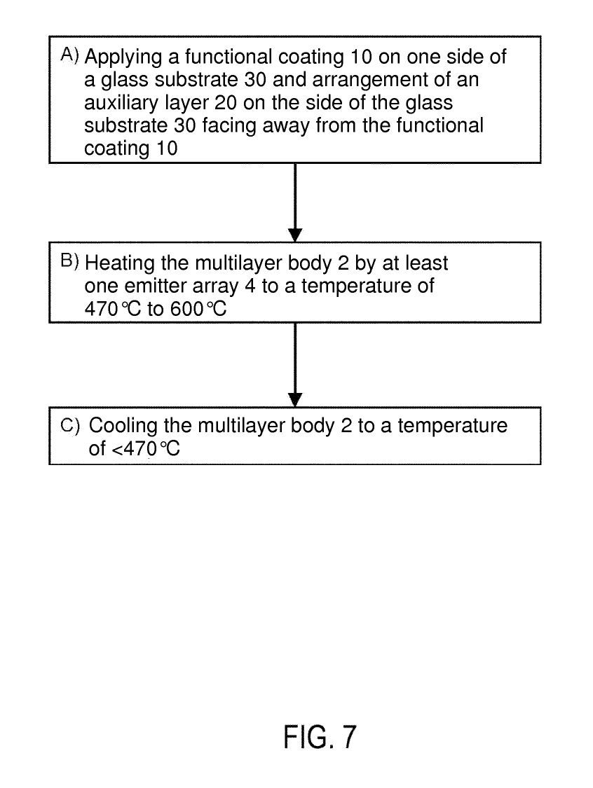

FIG. 7 an exemplary embodiment of the steps of the method according to the invention using a flow diagram.

FIG. 1 depicts a multilayer body arrangement 1 according to the invention for heat-treating a functional coating 10 on a glass substrate 30. The multilayer body arrangement 1 is, for example, a portion of a heating chamber (not shown) of an in-line system for heat-treating a functional coating 10 of precursor layers of a thin-film solar cell by rapid thermal processing (RTP). The in-line system further has a cooling chamber that is disposed after the heating chamber in the transport direction. The multilayer body 2 is situated on a process level 3 that is disposed between two emitter arrays 4.1 and 4.2. The emitter arrays 4.1 and 4.2 comprise, for example, a plurality of linear emitters disposed in parallel.

The multilayer body 2 includes, for example, a glass substrate 30 with a functional coating 10 on the top side of the glass substrate 30. The functional coating 10 includes, for example, a molybdenum electrode and a stack sequence of precursor layers that include copper, indium, gallium, sulfur, and selenium.

The functional coating 10 can equally possibly be disposed on the bottom side of the glass substrate 30 and the auxiliary layer 20 on the top side of the glass substrate 30. The multilayer body 2 can also be disposed vertically between the emitter arrays 4.1 and 4.2.

The multilayer body 2 is heated by radiation of the power Pₒ of the upper emitter array 4.1 and Pᵤ of the lower emitter array 4.2. The different layers of the multilayer body 2, i.e., the functional coating 10, the glass substrate 30, and the auxiliary layer 20, have absorption coefficients A₁₀, A₂₀, and A₃₀, reflection coefficients R₁₀, R₂₀, and R₃₀, and transmission coefficients T₁₀, T₂₀, and T₃₀, defined relative to the incident radiation. These coefficients for radiation from the upper emitter array 4.1 or from the lower emitter array 4.2 can be differentiated by using different radiation sources or with different characteristics of the top sides and the bottom sides of the individual layers. For purposes of illustration, it is simply assumed here that these coefficients are identical for the radiation of the power Pₒ and Pᵤ emitted from the upper emitter array 4.1 and lower 4.2 emitter array.

Table 1 reports the radiated power absorbed in the individual layers, emitted from the upper 4.1 and lower 4.2 emitter array. The total absorbed radiated power in the respective layer that is caused by the radiation of the upper emitter array 4.1 and the lower 4.2 emitter array, is presented in in the right column of the table 1.

TABLE 1

| | | Absorbed | |
|---|---|---|---|
| | Absorbed Power | Power from the | |
| | from the Upper | Lower Emitter | |
| | Emitter Array 4.1 | Array Array 4.2 | Total Absorbed |
| | with Power Po | with Power Po | Power |
| Functional | Pₒ × A₁₀ | Pᵤ × T₂₀ × T₃₀ × | P₁₀ = (Pₒ × A₁₀) + |
| coating 10 | | A₁₀ | (Pᵤ × T₂₀ × T₃₀ × |
| | | | A₁₀) |
| Substrate | Pₒ × T₁₀ × A₃₀ | Pᵤ × T₂₀ × A₃₀ | P₃₀ = (Pₒ × T₁₀ × |
| 30 | | | A₃₀) + (Pᵤ × T₂₀ × |
| | | | A₃₀) |
| Auxiliary | Pₒ × T₁₀ × T₃₀ × | Pᵤ × A₂₀ | P₂₀ = (Pₒ × T₁₀ × |
| layer 20 | A₂₀ | | T₃₀ × A₂₀) + (Pᵤ × |
| | | | A₂₀) |

An ideal multilayer body 2 according to the invention is now characterized by the condition P₁₀=P₂₀, i.e., the total absorbed power P₁₀ of the functional coating 10 is equal to the total absorbed power P₂₀ of the auxiliary layer 20.

The ideal case described is, in reality, difficult to implement. A reduction of substrate deformation according to the invention by means of the symmetrization of the temperature gradient in the glass substrate 30 can, however, be obtained in all cases if the absorbed power P₂₀ of the functional coating 20 satisfies the following conditions:

For P₁₀>P₃₀, the following must be true: P₂₀>P₃₀, or

for P₁₀<P₃₀, the following must be true: P₂₀<P₃₀.

The conditions are true even for the case that only one emitter array is available per substrate, or the radiated power Pₒ and Pᵤ (top and bottom side) is different. The conditions are likewise true in the case of different wavelength maxima of the upper emitter array 4.1 and the lower emitter array 4.2.

The functional coating 10 and the auxiliary layer 20 can, in each case, also consist of a plurality of layers. The conditions stated then apply for the absorption, reflection, and transmission characteristics of the entire packet comprising the functional coating 10 or auxiliary layer 20.

It is advantageous for the reflection R₂₀ of the auxiliary layer 20 to be as little as possible. For the reduction of deformation according to the invention, in accordance with the above mentioned conditions, only the power actually absorbed is of significance. Consequently, even layers with relatively high reflection could be used. However, in this case, the heat output necessary for the thermal process increases. Values of interest in practice for the reflection R₂₀ B begin, for example, at R₂₀<70%. A significant contribution to the reduction of substrate deformation is already anticipated for absorption values A₂₀ of the auxiliary layer 20 of A₂₀>5%.

FIG. 2a schematically depicts the curve of the temperature T over the substrate height z of the glass substrate 30 during heat treatment in an emitter array in accordance with FIG. 1. FIG. 2a depicts the temperature curve over a multilayer body 2 according to FIG. 1. If functional coating 10, auxiliary layer 20, and glass substrate 30 in each case absorb roughly the same power, i.e., P₁₀=P₂₀=P₃₀, this yields a constant temperature curve (i) over the substrate height z. Because of the relatively low radiation absorption A₃₀ of the glass substrate 30 compared to the radiation absorption A₁₀ of the functional coating 10, this case can be obtained only with great difficulty. However, a reduction in the deformation of glass substrate 30 already occurs through a symmetrization of the temperature curve when P₁₀>P₃₀ with P₂₀>P₃₀. The resultant temperature distribution ii) shows temperature maxima in the area of the glass substrate 30 on the boundaries with the functional coating 10 and with the auxiliary layer 20.

FIG. 2B depicts the temperature curve of a glass substrate 30 with a functional coating 20 on one side according to the prior art without auxiliary layer 20. The temperature curve is asymmetric and inhomogenous. In particular, the temperature T in the region of the functional coating 20 is higher than on the bottom side of the glass substrate 30, on which there is no coating. After cooling, a clear deformation of the glass substrate 30 due to the chain of problems described in the introduction is noted.

FIG. 3 depicts a preferred embodiment of the multilayer body 2 according to the invention. The functional coating 10 includes a barrier layer 11 made of silicon nitride, which serves as a diffusion barrier for sodium ions out of the glass substrate 30. In addition, the functional coating 10 includes an electrode 12, which, for example, contains molybdenum or is made of molybdenum. A precursor layer 13 consisting of a layer sequence or an alloy that includes copper, indium, and/or gallium as well as an additional precursor layer 14 made of selenium is disposed on the electrode 12. The precursor layer 13 can be transformed by heat-treating into an absorber layer of the thin-film solar cell, for example, in a sulfur-containing atmosphere. The thickness of the barrier layer 11 made of a silicon nitride layer is preferably from 50 nm to 300 nm and, for example, 150 nm. The thickness of the electrode 12 is preferably from 200 nm to 700 nm and, for example, 500 nm. The thickness of the precursor layer 13 is preferably from 300 nm to 1000 nm and, for example, 700 nm. The thickness of the other layer 14 made of selenium is preferably from 700 nm to 2000 nm and, for example, 1500 nm. Other materials for the barrier layer 11 are, for example, silicon oxynitride, aluminum oxide, molybdenum nitride, titanium nitride, or mixtures or layer sequences thereof. The electrode 12 preferably includes copper, aluminum, titanium, or mixtures or layer sequences thereof. The precursor layer 13 can also include aluminum, sulfur, zinc, tin, or silver.

An auxiliary layer 20 is disposed on the side of the glass substrate 30 facing away from the functional coating 10. An important condition for the auxiliary layer 20 is chemical and thermal stability. In this exemplary embodiment, the auxiliary layer 20 consists of a single (partially) absorbing layer, chemically inert relative to the process products of the precursor layers 13 and 14. The production methods for Cu(In,Ga)(S,Se)₂-thin-film solar cells require, for example, temperature stability for temperatures up to roughly 600° C. and chemical stability relative to selenium vapor and sulfur vapor as well as hydrogen sulfide and hydrogen selenide.

The auxiliary layer 20 preferably includes graphite, silicon nitride, or boron nitride. The auxiliary layer consists, for example, of a graphite layer with a thickness of 200 nm.

The auxiliary layer 20 has, depending on the production or deposition method, a thickness from 10 nm to 10 μm. The lower limit depends on the desired degree of transmission and the optical properties of the layer. The optimum thickness can be determined by simple experiments. The deposition of the auxiliary layer 20 is preferably carried out by plasma methods under a vacuum, such as cathode sputtering by vapor deposition, by chemical gas phase deposition (chemical vapor deposition CVD) such as plasma CVD, by electrodeposition, and/or by spray methods.

FIG. 4 depicts an alternative embodiment of a multilayer body 2 according to the invention. The functional coating 20 corresponds to the layers described under FIG. 3. The auxiliary layer 20 includes a stack sequence made up of an adhesive layer 21, an absorption layer 23, and a protective layer 22, with the first barrier layer 21 disposed directly adjacent the glass substrate 30. The adhesive layer 21 and protective layer 22 are substantially transparent and include dielectric material. In the context of this invention, “substantially transparent” means a transmission of more than 98% for the incident electromagnetic radiation of the emitter array 4.

The protective layer 22 is advantageously inert relative to the process products during the heat treatment of the precursor layers 13 and 14 and, in particular, inert relative to selenium-containing and/or sulfur-containing atmospheres at high temperatures. The adhesive layer 21 is an adhesion-promoting or adhesion-improving layer that fixedly bonds the absorption layer 13 and the protective layer 22 to the glass substrate.

Advantageously, the adhesive layer 21 includes silicon nitride or silicon oxynitride. The thickness of the adhesive layer 21 is advantageously from 0 nm to 300 nm. The adhesive layer is, for example, a silicon nitride layer.

The protective layer 22 preferably includes silicon nitride, titanium nitride, molybdenum nitride, aluminum oxide, and/or aluminum nitride. The thickness of the protective layer 22 is advantageously from 50 nm to 500 nm. The protective layer 22 is, for example, a silicon nitride layer with a thickness of 1500 nm.

Such adhesive layers 21 and protective layers 22 prevent the diffusion of alkali metals out of the glass substrate 30 and into the precursor layers 13 and 14. Uncontrolled diffusion of alkali metals into the precursor layers 13,14 or the semiconductor absorber layer produced therefrom reduces the efficiency and negatively affects the electrical properties of the subsequent thin-film solar cell.

Simple metal layers are suitable as a sole auxiliary layer 20 only to a limited extent since the reactivity with selenium and sulfur is usually too strong and the metal layers corrode. Moreover, the reflection of thin and smooth metal layers is disadvantageously high.

If the metal layer is protected against the process atmosphere by a protective layer 22, metal layers can be used as absorption layer 23. Suitable metals include, in particular, aluminum, molybdenum, copper, cobalt, nickel, titanium, tantalum, or alloys thereof. To reduce the reflection, it can be further advantageous to form a porous and/or rough surface on the metal layer by deposition.

The absorption layer 23 can advantageously include a semiconductor or a metalloid. Particularly suitable are amorphous silicon germanium, silicon carbide, zinc oxide, cadmium sulfide, cadmium telluride, indium antimonide, indium arsenide, and/or zinc antimonide. With these semiconductors, the absorption behavior can be adjusted by the band gap and the number of free charge carriers and optimized relative to the incident radiation. In the semiconductors with small band gaps such as indium arsenide and zinc antimonide, the absorption of interest at the time of electromagnetic radiation with energy for this application is above the band gap. Semiconductors with large band gaps such as zinc oxide are, to be sure, transparent in the visible range, but have increased absorption for wavelengths above a critical wavelength determined by the plasma frequency.

In an advantageous embodiment of the auxiliary layer 20 according to the invention, the index of refraction and the layer thickness of the protective layer 22 are adjusted such that the protective layer 22 acts as an anti-reflection layer. The layer parameters are preferably to be selected such that the minimum of the reflection lies at the maximum of the spectral distribution of the electromagnetic radiation of the emitter arrays 4. In the case of a protective layer 22 made of a single-ply silicon nitride layer, this is, for example, a layer thickness of roughly 400 nm. The protective layer 22 can even be a gradient layer with a different index of refraction along the layer thickness or again a dielectric multi-ply layer, in order to increase the anti-reflective effect.

FIG. 5 depicts a particularly advantageous exemplary embodiment of a simplified auxiliary layer 20. The auxiliary layer 20 has and absorption layer 23 made of molybdenum and a protective layer 22 made of silicon nitride. This layer sequence has the particular advantage that the absorption layer 23 made of molybdenum adheres well to the glass substrate 30 and the combination molybdenum/silicon nitride has, at the same time, an adequate diffusion barrier effect for alkali metals out of the glass substrate 30.

FIG. 6 depicts an alternative embodiment of a multilayer body arrangement 1 according to the invention with two glass substrates 30.1 and 30.2 in a process box 50. This arrangement is customarily referred to as a dual substrate configuration. The functional layers 10.1 and 10.2 are disposed here directly adjacent each other (face-to-face configuration) and held a fixed distance apart by spacing elements 51.

The auxiliary layers 20.1 and 20.2 are, for example, disposed on carrier plates 40 such as a cover plate 41 or base plate 42. A frame element 52 forms the process space with the cover plate 41 and the base plate 42. The carrier plate 40 includes, for example, a glass ceramic that is substantially transparent to the electromagnetic radiation 5 of the emitter arrays 4.1 and 4.2.

The symmetrisation according to the invention of the temperature gradient occurs here through thermal contact of the auxiliary layers 20.1 and 20.2, which are die releasably connected to the glass substrates 30.1 and 30.2. The thermal contact with the lower glass substrate 10.2 occurs, for example, by placing the side of the glass substrate 30.2 facing away from the functional coating 10.2 on the auxiliary layer 20.2. The auxiliary layer 20.2 is, in turn, disposed on the base plate 42 of the process box 50. Alternatively, the thermal contact with the upper glass substrate 10.1 occurs by placement of the auxiliary layer 20.1 on the side of the glass substrate 30.1 facing away from the functional layer 10.1. The auxiliary layer 20.1 is disposed on the bottom side of the cover plate 41. The auxiliary layers 20.1 and 20.2 can be materials that are inert relative to the process products at high temperatures and, in particular, sulfur and selenium, such as, for example, graphite, silicon carbide, or boron nitride, as was described under FIG. 3. The auxiliary layers 20.1 and 20.2 can, however, also be multilayer systems of absorption layers 23 and protective layers 22, as were already described under FIG. 4 and FIG. 5. It is understood that the absorption layer 23 is in this case disposed preferably directly on the carrier plate 40 and the protective layer 22 shields the absorption layer 23 relative to the process space. This has the particular advantage that the protective layer 22 protects the absorption layer 23 against reactive process products and mechanical destruction in the case of contact with the glass substrate.

The present invention is not limited to arrangements with one or two glass substrates 30. Moreover, two glass substrates 30.1 and 30.2 can be disposed such that the functional coatings 10.1 and 10.2 face away from each other and are separated from each other by the glass substrates 30.1 and 30.2 (back-to-back configuration). A carrier plate (not shown here) that is coated on both sides with an auxiliary layer 20 in each case can be situated between the two glass substrates 30.1 and 30.2.

The carrier plate with the auxiliary layer 20 does not have to be part of a process box, but can instead be, for example, the base of a conveyor belt or simply lie on the glass substrate 30 as a separate element.

FIG. 7 depicts an exemplary embodiment of the process steps according to the invention using a flowchart.

Glass substrates 30, whose temperature profile are [sic] made symmetrical by an auxiliary layer 20 according to the invention, have, after heat treatment, less deformation than similar glass substrates 30 that were processed without an auxiliary layer 20.

This result was unexpected and surprising for the person skilled in the art.

### LIST OF REFERENCE CHARACTERS

1 multilayer body arrangement
2 multilayer body
3 process level
4, 4.1, 4.2 emitter array
5 electromagnetic radiation
10, 10.1, 10.2 functional coating
11 barrier layer
12 electrode
13 precursor layer
14 additional precursor layer
20, 20.1, 20.2 auxiliary layer
21 adhesive layer
22 protective layer
23 absorption layer
30, 30.1, 30.2 glass substrate
41 base plate
42 cover plate
50 process box
51 spacing element
52 frame element
z substrate thickness
T temperature

1. Multilayer body arrangement for the prevention of glass substrate deformation, comprising:
a glass substrate,
a functional coating, which is applied on one side of the glass substrate,
an auxiliary layer, which is connected over its entire area to the side of the glass substrate facing away from the functional coating,
at least one emitter array with a radiated power Pₜₒₜ in the wavelength range from 250 nm to 4000 nm incident on the glass substrate for heat-treating the functional coating,
wherein the auxiliary layer has an absorbed radiated power P₂₀ from 10% to 60% of the incident radiated power Pₜₒₜ.

2. Multilayer body arrangement according to claim 1, wherein the auxiliary layer is applied on the glass substrate, preferably by vapor deposition, cathode sputtering, or electrochemical deposition.

3. Multilayer body arrangement according to claim 1, wherein the auxiliary layer is releasably connected to the glass substrate.

4. Multilayer body arrangement according to claim 3, wherein the auxiliary layer is applied on a carrier plate of a process box.

5. Multilayer body arrangement according to claim 1, wherein the auxiliary layer has an absorbed radiated power P₂₀ from 10% to 40% and preferably from 20% to 30% of Pₜₒₜ.

6. Multilayer body arrangement (1) according to claim 1, wherein the auxiliary layer has an absorbed radiated power P₂₀ from 50% to 150% of the radiated power P₁₀ absorbed in the functional coating.

7. Multilayer body arrangement according to claim 1, wherein the auxiliary layer includes at least one layer made of graphite, silicon carbide, and/or boron nitride.

8. Multilayer body arrangement according to claim 1, wherein the auxiliary layer includes an absorption layer disposed on the glass substrate and a protective layer disposed on the absorption layer.

9. Multilayer body arrangement according to claim 8, wherein the absorption layer includes a metal or a metalloid compound and/or the protective layer contains silicon nitride, titanium nitride, molybdenum nitride, aluminum oxide, and/or aluminum nitride.

10. Multilayer body arrangement according to claim 1, wherein the auxiliary layer has an adhesive layer between the glass substrate and the absorption layer.

11. Multilayer body arrangement according to claim 1, wherein the functional coating includes precursor layers for conversion into a semiconductor layer of a thin-film solar cell.

12. Multilayer body arrangement according to claim 1, wherein the functional coating includes at least one barrier layer an electrode, a precursor layer, and an additional precursor layer.

13. Method for heat-treating with a multilayer body arrangement according to claim 1, wherein:
a) a functional coating is applied on one side of a glass substrate, and the side of the glass substrate facing away from the functional coating is connected to an auxiliary layer,
b) the glass substrate is heated to a temperature of 470° C. to 600° C. by at least one emitter array with a radiated power Pₜₒₜ in the wavelength range from 250 nm to 4000 nm incident on the glass substrate, wherein a radiated power P₂₀ von 10% to 60% of the incident radiated power Pₜₒₜ is absorbed by the auxiliary layer, and,
c) the glass substrate is cooled to a temperature of <470° C.

14. Method according to claim 13, wherein the auxiliary layer is applied on the glass substrate by vapor deposition, cathode ray sputtering, and/or chemical gas phase deposition.

15. (canceled)

16. Multilayer body arrangement according to claim 4, wherein the carrier plate is a base plate or a cover plate of a process box.

17. Multilayer body arrangement according to claim 7, wherein the at least one layer has a layer thickness of 10 nm to 10 μm.

18. Multilayer body arrangement according to claim 9, wherein the metal is aluminum, molybdenum, copper, cobalt, nickel, titanium, and/or tantalum.

19. Multilayer body arrangement according to claim 9, wherein the metalloid compound is silicon carbide, zinc oxide, cadmium sulfide, cadmium telluride, indium antimonide, indium arsenide, and/or zinc antimonide.

20. Multilayer body arrangement according to claim 10, wherein the adhesive layer includes silicon nitride and/or silicon oxynitride.

21. Multilayer body arrangement according to claim 11, wherein the precursor layers are made of copper, indium, gallium, sulfur, and/or selenium.
